(19) United States
(12) Patent Application Publication
(10) Pub. No.: US 2025/0240917 A1
(43) Pub. Date: Jul. 24, 2025

(54) LIQUID COOLING SYSTEM AND SERVER

(71) Applicant: SHENZHEN ENVICOOL TECHNOLOGY CO., LTD., Shenzhen (CN)

(72) Inventors: Xiaoxin XU, Shenzhen (CN); Xiaolei AI, Shenzhen (CN)

(73) Assignee: SHENZHEN ENVICOOL TECHNOLOGY CO., LTD., Shenzhen (CN)

(21) Appl. No.: 18/806,061

(22) Filed: Aug. 15, 2024

(30) Foreign Application Priority Data
Jan. 19, 2024 (CN) 202410084896.X

(51) Int. Cl. H05K 7/20

(52) U.S. Cl. CPC H05K 7/20272; H05K 7/20772

(57) ABSTRACT

The present application relates to a liquid cooling system including a liquid cooling body, a liquid guide tube, a liquid collection structure and a suction device. The liquid cooling body is configured to exchange heat with a heating element and is communicated with the liquid guide tube. The liquid collection structure is configured to collect liquid leaking from the liquid cooling body and/or the liquid guide tube. The suction device has a negative-pressure channel, the negative-pressure channel has a suction opening and is arranged at the liquid collection structure, and is configured to be connected to the suction apparatus to suck liquid from the liquid collection structure into the negative-pressure channel and discharge or store the liquid through the negative-pressure channel. The present application further discloses a server including the liquid cooling system.

### CROSS REFERENCE TO RELATED APPLICATIONS

The present application claims priority to Chinese Patent Application No. 202410084896.X, titled “LIQUID COOLING SYSTEM AND SERVER”, filed on Jan. 19, 2024 with the China National Intellectual Property Administration, which is incorporated herein by reference in its entirety.

### FIELD OF THE INVENTION

The present application relates to the technical field of heat dissipation, and in particular to a liquid cooling system and a server.

### BACKGROUND

With the increase of the power density of servers, there is a high requirement for heat dissipation. Compared with the air cooling heat exchange, the liquid cooling heat exchange can provide higher heat exchange efficiency to meet heat exchange requirements of servers. At present, the liquid cooling for servers mainly adopts cold plate liquid cooling, also known as a liquid cooling plate. The liquid cooling plate exchanges heat with a high heat-generating element of a server, and then quickly transfer heat to the outside of the server by being connected to a heat exchange device through a liquid inflow or outflow pipe.

During the operation of the server, a leakage may occur at positions such as a liquid cooling plate, liquid inflow and outflow pipes, or the welding joints between the liquid cooling plate and the liquid inflow and outflow pipes due to fatigue, vibration, etc. If the electronic components of the server come into contact with the leaking high-pressure liquid, a fault such as a short circuit may occur. Therefore, it is necessary to detect whether there is a leakage in the liquid cooling system, and perform an operation such as shutdown in time when a leakage is detected. Although the above operation can reduce the possibility of failure of the server due to water exposure, the time limit of the operation is relatively short and it is necessary to operate quickly within a short time. Usually, an emergency forced power outage is required. Otherwise, the continuous leakage of liquid may easily cause failure of the electronics, making it difficult to store data.

### SUMMARY

In view of the above, the object of the present application is to provide a liquid cooling system and a server. The liquid cooling system and the server are structured to suck, discharge or store leaking liquid, so as to delay the impact of leakage of the liquid cooling system on the electronics and provide sufficient operation time for related operations after leakage.

In order to achieve the above object, the present application provides the following technical solution.

A liquid cooling system includes a liquid cooling body for exchanging heat with a heating element and a liquid guide tube communicated with the liquid cooling body. The liquid cooling system further includes a liquid collection structure and a suction device. The liquid collection structure is configured to collect liquid leaking from at least one of the liquid cooling body and the liquid guide tube. The suction device has a negative-pressure channel. The negative-pressure channel has a suction opening and is arranged at the liquid collection structure, and the negative-pressure channel is configured to be connected to a suction apparatus so that the liquid in the liquid collection structure can be pumped into the negative-pressure channel and be discharged or stored through the negative-pressure channel.

In an embodiment, in the liquid cooling system, the liquid collection structure has a collection area with a reduced height, and the suction opening is arranged at the collection area.

In an embodiment, in the liquid cooling system, the suction device includes a suction tube and a connector fixedly arranged on the liquid collection structure, and a portion of the connector extends to above the collection area and is connected to the suction tube.

In an embodiment, in the liquid cooling system, a protruding portion is provided on a bottom surface, facing the collection area, of the connector, and the protruding portion extends into the collection area. A first preset gap is formed between a bottom surface of the protruding portion and a bottom surface of the collection area, and a second preset gap is formed between an outer circumferential surface of the protruding portion and a side wall of the collection area. The connector is provided with a through hole at a position corresponding to the collection area, and the suction tube is disposed at the through hole.

In an embodiment, in the liquid cooling system, at least part of a projection of the connector on a plane, where an edge of a top of the collection area is located, is located in the collection area; and/or, a bottom surface of a portion, located above the collection area, of the connector is located at a preset distance above the top of the collection area.

In an embodiment, in the liquid cooling system, the suction tube is threadedly connected to the connector.

In an embodiment, in the liquid cooling system, the end face of the liquid collection structure is provided with multiple drainage ribs. The multiple drainage ribs converge and correspond to the suction opening at an end thereof, and diverge and extend towards the periphery of the liquid collection structure at the other end thereof.

In an embodiment, the liquid cooling system includes multiple liquid collection structures. The suction device includes negative-pressure channels respectively corresponding to the multiple liquid collection structures, and the negative-pressure channels are in communication with each other.

In an embodiment, the liquid cooling system further includes a detection device for detecting the liquid in the liquid collection structure, and the suction apparatus is configured to be started when a preset amount of liquid is detected in the liquid collection structure by the detection device.

In an embodiment, in the liquid cooling system, a bump is provided on an end face provided with the suction opening of the suction device to abut against an end face of the liquid collection structure, so that a gap is formed between the end face provided with the suction opening of the suction device and the end face of the liquid collection structure.

The liquid cooling system according to the present application includes a liquid cooling body, a liquid guide tube, a liquid collection structure, and a suction device. The liquid cooling body is configured to exchange heat with a heating element. The liquid guide tube is communicated with the liquid cooling body, and the liquid collection structure is configured to collect the liquid leaking from at least one of the liquid cooling body and the liquid guide tube. The suction device has a negative-pressure channel. The negative-pressure channel has a suction opening and is arranged at the liquid collection structure, and the negative-pressure channel is configured to be connected to a suction apparatus to pump the liquid from the liquid collection structure into the negative-pressure channel and to discharge or store the liquid through the negative-pressure channel.

In the liquid cooling system according to the present application, the liquid collection structure is provided to collect the liquid leaking from the liquid cooling body or the liquid guide tube, so as to prevent the liquid from directly leaking to the electronic devices, thereby improving the safety of the system. With arrangement of the suction device, the liquid can be drawn out of the liquid collection structure under the negative pressure generated at the suction opening of the liquid collection structure after the suction apparatus is started, and be discharged or stored through the negative-pressure channel. As can be seen, on the one hand, the collection path of the leaking liquid is further prolonged through the suction device, which can delay the influence of the leakage of the liquid cooling system on the electronic apparatus and provide sufficient operation time for related operations such as data storage or normal shutdown after the leakage. On the other hand, the negative pressure suction reduces the spatial requirements of the layout. For example, the negative-pressure channel can fully utilize the vertical space, which facilitates the overall structural layout. The negative pressure suction facilitates pumping the leaking liquid to the outside of the apparatus so as to be discharged as waste liquid, or facilitates pumping the leaking liquid to the area away from the electronic devices.

To achieve the above object, a server is further provided according to the present application, which includes the liquid cooling system described above. Since the liquid cooling system has the above technical effects, the server including the liquid cooling system also has corresponding technical effects.

### BRIEF DESCRIPTION OF THE DRAWING

In order to more clearly illustrate the technical solutions in the embodiments of the present application or in the conventional technology, the following will briefly introduce drawings required in the description of the embodiments or the conventional technology. Apparently, the drawings in the following description are only some of the embodiments of the present application. For those skilled in the art, other drawings can also be obtained based on these drawings without creative efforts.

FIG. 1 is a schematic structural view of a liquid cooling system according to an embodiment of the present application;

FIG. 2 is a schematic view of the partial internal structure of the liquid cooling system shown in FIG. 1;

FIG. 3 is a top view of a liquid collection structure and a connector in FIG. 1;

FIG. 4 is a schematic cross-sectional view taken along line A-A in FIG. 3;

FIG. 5 is an enlarged schematic view of part A in FIG. 4; and

FIG. 6 is a top view of the liquid collection structure in FIG. 3.

The reference signs in the figures are listed as follows:

liquid cooling body 1,
liquid guide tube 2,
liquid collection structure 3,
suction device 4;
collection area 31,
suction opening 401,
suction tube 41,
connector 42,
protruding portion 421,
first preset gap L1,
second preset gap L2,
through hole 402.

### DETAIL DESCRIPTION OF EMBODIMENTS

A liquid cooling system and a server are disclosed according to the embodiments of the present application to collect, suck, discharge or store leaking liquid, thereby delaying the impact of leakage of the liquid cooling system on electronics and allowing more time for related operations after leakage.

The technical solutions in the embodiments of the present application are clearly and completely described below in conjunction with the drawings. Apparently, the described embodiments are only part of the embodiments of the present application, not all of the embodiments of the present application. Any other embodiment obtained by those skilled in the art based on the embodiments in the present application without creative efforts shall fall within the protection scope of the present application.

The liquid cooling system according to the present application includes a liquid cooling body and a liquid guide tube communicated with a corresponding liquid cooling body or corresponding liquid cooling bodies. The liquid cooling body is generally a liquid cooling plate, but in some cases, the liquid cooling body may be of a block structure or any other structure. The liquid cooling body is configured to exchange heat with a heating element of an electronic apparatus such as a server. It can be understood that the heating element may include an element such as a processor that generates heat itself during operation, or an element that is heated indirectly by absorbing heat generated by the self-heat generating element. The liquid cooling body has at least one heated surface, which is configured to abut against an electronic element to be cooled. As such, the heated surface of the liquid cooling body and a heat dissipation surface of the electronic element are in thermal contact.

The liquid guide tube is configured to discharge a high-temperature liquid out of the liquid cooling body and introduce a low-temperature liquid into the liquid cooling body. It should be noted that the liquid in the liquid cooling body and the liquid guide tube in the present application may be cooling water or refrigerant. The cooling water includes, but is not limited to, water or a mixture of water, e.g., anti-freezing cooling water added with ethylene glycol. The refrigerant includes, but is not limited to, a refrigerant added with fluorine.

In the present application, the guide tube has a liquid inflow channel and a liquid outflow channel for liquid circulation, so as to allow the high-temperature liquid in the liquid cooling body to flow out and allow the low-temperature liquid to flow in the liquid cooling body. It can be understood that the guide tube may include a liquid inflow tube and a liquid outflow tube which are arranged separately, or may include a multi-cavity tube that is integrally arranged and has different cavities respectively for inflow and outflow of liquid. In the present application, since the liquid cooling body and the liquid guide tube may leak, a corresponding structure is provided to reduce the impact of leaking liquid on electronic devices in an apparatus including the liquid cooling system. In the following embodiments, the above structure is mainly described, and other structures of the liquid cooling system may refer to the conventional technology, which are not repeated here.

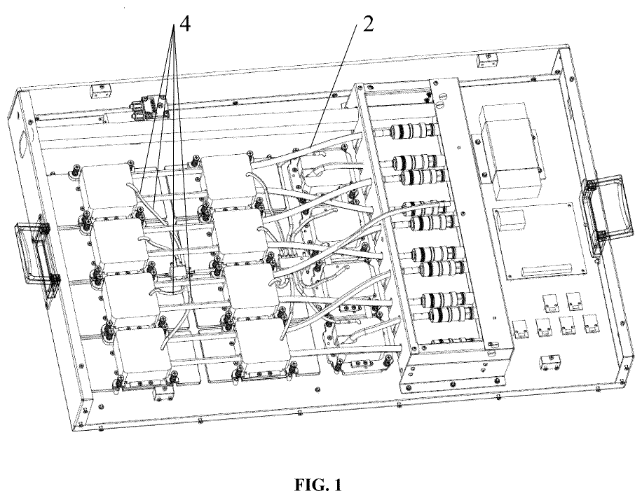

In an embodiment, referring to FIGS. 1 to 4, the liquid cooling system according to the present application includes a liquid cooling body 1, a liquid guide tube 2, a liquid collection structure 3, and a suction device 4. The liquid collection structure 3 is configured to collect liquid leaking from at least one of the liquid cooling body 1 and the liquid guide tube 2. The shape and position of the liquid collection structure 3 may be set as needed, which is not specifically limited herein. The suction device 4 has a negative-pressure channel, which may be formed by an inner cavity of a tube or a hollow channel defined by a wall surface of another structure such as a housing. The negative-pressure channel has a suction opening 401 located in the liquid collection structure 3. The negative-pressure channel is configured to be connected to a suction apparatus. The suction apparatus is started to create a negative pressure in the negative-pressure channel, so that the liquid in the liquid collection structure 3 can be sucked through the suction opening 401 into the negative-pressure channel and can be discharged or stored through the negative-pressure channel. According to the specific working condition of the liquid cooling system, the negative-pressure channel may also be in a normal pressure state when the suction apparatus is not started. It can be understood that the liquid may be pumped to the outside of an apparatus equipped with the liquid cooling system by designing a route or a path of the negative-pressure channel. For example, the end of the negative-pressure channel away from the suction opening 401 extends to a housing of the apparatus and is communicated with the outside of the apparatus so as to discharge the pumped liquid as waste liquid, or the end of the negative-pressure channel away from the suction opening 401 is communicated with a storage device outside the apparatus so as to store the waste liquid. Alternatively, the liquid may be pumped to an area away from the electronic devices for storage by designing the route and the path of the negative-pressure channel. For example, the liquid may be pumped into a storage bottle of the apparatus for storage.

In the liquid cooling system according to the present application, the liquid collection structure 3 is provided to collect the liquid leaking from the liquid cooling body 1 or the liquid guide tube 2, so as to prevent the liquid from directly leaking to the electronic devices, thereby improving the safety of the system. With arrangement of the suction apparatus, after the suction apparatus is started, the negative pressure is generated at the suction opening 401 of the liquid collection structure 3 to suck the liquid out of the liquid collection structure 3, and the liquid is discharged or stored through the negative-pressure channel. As can be seen, on the one hand, the suction device 4 further prolongs a collection path of the leaking liquid, which can delay the influence of the leakage of the liquid cooling system on the electronic apparatus and provide sufficient operation time for related operations after the leakage, e.g., data storage or normal shutdown. On the other hand, the negative pressure suction reduces the spatial requirements of the arrangement. For example, the negative-pressure channel can fully utilize the vertical space, which facilitates the overall structural arrangement. The negative pressure suction facilitates discharging the leaking liquid to the outside of the apparatus as waste liquid, or facilitates pumping the leaking liquid to the area away from the electronic devices.

In some embodiments, the liquid cooling system is provided with a suction apparatus, that is, the negative-pressure channel is connected to the suction apparatus disposed in the liquid cooling system. The suction apparatus is used to form a negative pressure in the negative-pressure channel to collect the liquid in the liquid collection structure 3. In other embodiments, the liquid cooling system may not be provided with the suction apparatus, and the negative-pressure channel is provided with a corresponding interface and is externally connected to a suction apparatus via the interface so that the negative pressure can also be formed in the negative-pressure channel. The suction apparatus includes, but is not limited to, a water pump, the power of which may be selected or set according to a suction force required, which is not specifically limited here.

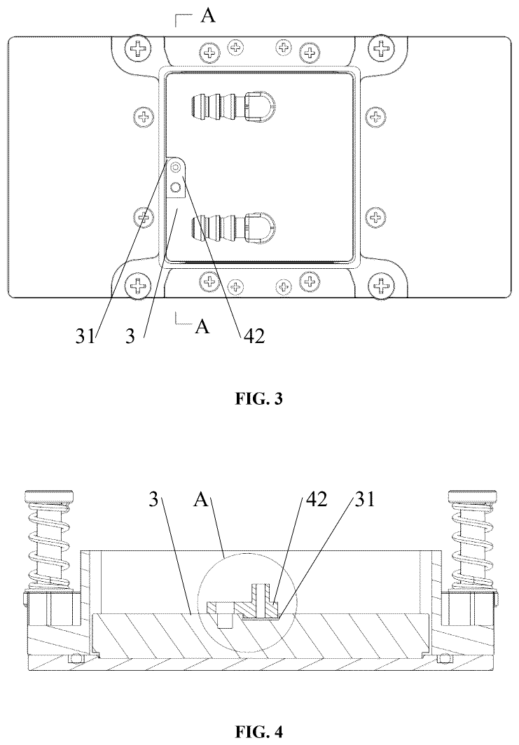

In some embodiments, referring to FIGS. 3 to 6, the liquid collection structure 3 has a collection area 31 with a reduced height, and the suction opening 401 is located in the collection area 31. It can be understood that the term “height” refers to a vertical height. The collection area 31 is formed by a partially concaved or tilted end face of the liquid collection structure 3. The collection area 31 may be a collection groove. Since the liquid flows from a higher position to a lower position under its own gravity, the leaking liquid can be collected better towards the collection area 31 by providing the collection area 31 in the liquid collection structure 3. The suction opening 401 is arranged in the collection area 31, so that the leaking liquid can be efficiently pumped to the negative-pressure channel and discharged or stored through the negative-pressure channel. The shape, size, and position of the collection area 31 may be set according to the structure of the liquid collection structure 3 and the position of the suction device 4. In a case that the suction opening 401 is sized to be approximate to the size of the liquid collection structure 3 and has sufficient suction force, the height of the liquid collection structure 3 may be constant, that is, the collection area 31 may be omitted.

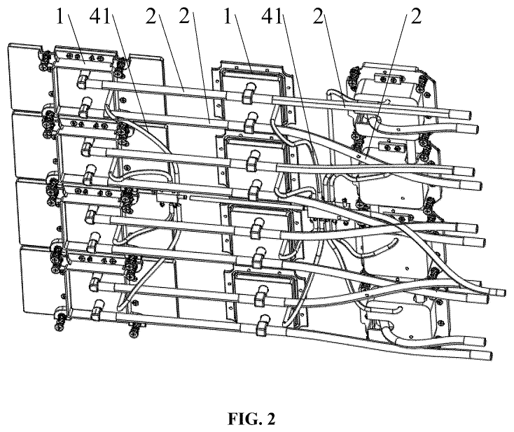

In some embodiments, referring to FIGS. 2 to 5, the suction device 4 includes a suction tube 41 and a connector 42. The connector 42 is fixedly arranged on the liquid collection structure 3, and partially extends beyond the collection area 31 to be connected to the suction tube 41. It can be understood that the connector 42 may be a structure separated from the suction tube 41, or may be a protruding portion formed on the outer tube wall of the suction tube 41, that is, the connector 42 may be a part of the suction tube 41. The suction tube 41 has a simple structure and occupies a small space, and extends according to the internal space of the apparatus. The connector 42 facilitates the mounting of the suction tube 41 to limit the position of the suction tube 41 relative to the collection area 31.

In some embodiments, the suction tube 41 is a metal tube, which has good deformability and bendability, so the suction tube 41 can be arranged according to space during the installation of pipeline, has good versatility, and is especially suitable for environments with complex internal spaces.

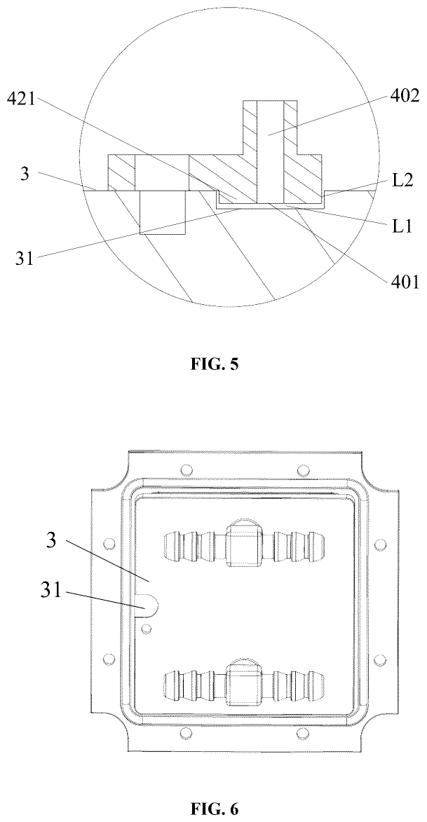

In some embodiments, referring to FIGS. 4 to 5, a protruding portion 421 is provided on a bottom surface, facing the collection area 31, of the connector 42. The protruding portion 421 extends into the collection area 31. A first preset gap L1 is formed between a bottom surface of the protruding portion 421 and a bottom surface of the collection area 31. A second preset gap L2 is formed between an outer circumferential surface of the protruding portion 421 and a side wall of the collection area 31. The connector 42 is provided with a through hole 402 corresponding to the position of the collection area 31, and the suction tube 41 is disposed at the through hole 402. It can be understood that the through hole 402 extends through the protruding portion 421, so that after the suction apparatus is started, a negative pressure can be formed between the bottom surface of the protruding portion 421 and the bottom surface of the collection area 31 to suck the liquid into the through hole. By the above arrangement, the small first preset gap L1 and the small second preset gap L2 are conducive to forming negative pressure to suck the leaking liquid. The second preset gap L2 can provide space for the leaking liquid on the end face of the liquid collection structure 3 to flow into the collection area 31. The sizes of the first preset gap L1 and the second preset gap L2 may be the same or different, and may be set as needed, which is not specifically limited here.

In some embodiments, referring to FIG. 6, the collection area 31 is arranged at an edge of one side of a liquid collection groove, and the collection area 31 includes a straight portion extending perpendicular to the edge and a hemispherical portion connected to the straight portion. The outer diameter of the hemispherical portion is equal to a width of the straight portion. The connector 42 includes a connection body in a plate shape and a pagoda joint located on the connection body. The connection body is arranged perpendicular to the straight portion. The connection body is provided with a bolt hole, and is fixedly connected to the liquid collection structure 3 through a bolt. A circular protrusion is provided on the bottom of the connection body, and the circular protrusion is inserted into the hemispherical portion and part of the straight portion. There are gaps between a bottom surface of the circular protrusion and a wall surface of the collection area 31 and between an outer circumferential surface of the circular protrusion and the wall surface of the collection area 31. The circular protrusion is provided with a through hole 402 in communication with the pagoda joint, and the pagoda joint is sealingly and fixedly connected to the suction tube 41. The above arrangement realizes full utilization of space, ensures the flow of leaking liquid to the collection area 31, facilitates the formation of negative pressure, and facilitates disassembly and assembly.

In some embodiments, at least part of a projection of the connector 42 on a plane, where an edge of a top of the collection area 31 is located, falls within the collection area 31; and/or, the bottom surface of a portion of the connector 42 located above the collection area 31 is located at a preset distance above the top of the collection area 31. It can be understood that the collection area 31 as a whole is located below the plane where the edge of the top of the collection area 31 is located. The plane where the edge of the top of the collection area 31 is located may be a horizontal plane, and at least part of the projection of the connector 42 on the horizontal plane falls within the collection area 31. In a case that the collection area 31 is a collection groove, the edge of the top of the collection area 31 is an edge of the groove opening of the collection groove. The portion of the connector 42 located above the collection area 31 may be provided with a through hole 402, and the suction tube 41 is provided at the through hole 402. At least part of the projection of the connector 42 on the plane falls within the collection area 31, so that the connector 42 does not block the top of the collection area 31, and thus the leaking liquid on the end face, provided with the collection area 31, of the liquid collection structure 3 can flow into the collection area 31. The suction tube 41 can be installed reliably without blocking the liquid on the end face from flowing into the collection area 31. Alternatively, there may be a preset distance between the bottom surface of the connector 42 located above the collection area 31 and the top of the collection area 31, that is, the connector 42 above the collection area 31 is located at a higher level than the top of the collection area 31, thereby providing space for the leaking liquid, which flows on the end face of the liquid collection structure 3 that is provided with the collection area 31, to flow into the collection area 31 without blocking the flow of the leaking liquid. In other embodiments, if the end face of the liquid collection structure 3 is not configured to collect the leaking liquid, for example, when the leaking liquid overflows upwards from a bottom channel of the collection area 31, the connector 42 may block the top of the collection area 31 to better form negative pressure.

In some embodiments, the suction tube 41 is sealingly disposed on the joint at the top of the connector 42, with the tube cavity of the suction tube 41 being communicated with the through hole 402. An opening at the bottom of the through hole 402 forms the suction opening 401.

Alternatively, the suction tube 41 may be sealingly disposed in the through hole 402, with the tube cavity of the suction tube 41 being communicated with the through hole 402. In the case that the bottom of the suction tube 41 is located inside the through hole 402, the opening at the bottom of the through hole 402 forms the suction opening 401. In the case that the bottom of the suction tube 41 extends out of the through hole 402, the opening at the bottom of the suction tube 41 forms the suction opening 401.

In an embodiment, the suction tube 41 is threadedly connected to the connector 42. The threaded connection is easy for disassembly and assembly, and can realize reliable connection by threads and effective sealing. The structure can be further simplified. Moreover, the threaded connection can realize continuous adjustment of the height of the suction tube 41 relative to the connector 42, so as to better cooperate with the collection area 31.

In some embodiments, in order to better form negative pressure, a gap is formed between the end face, provided with the suction opening 401, of the suction device 4 and the end face of the liquid collection structure 3. This gap may be specifically defined or formed by the structure of the suction device 4 and/or the installation position of the suction device 4 relative to the liquid collection structure 3. The provision of the gap can allow the flow of liquid, and facilitate the formation of negative pressure, so as to better achieve the suction of leaking liquid.

In an embodiment, a bump is provided on the end face, provided with the suction opening 401, of the suction device 4 to abut against the end face of the liquid collection structure 3, so that a gap is formed between the end face provided with the suction opening 401 of the suction device 4 and the end face of the liquid collection structure 3. The number of the bump may be one or more. The suction device 4 abuts against the liquid collection structure 3 by the bump, so that the gap is formed between the end face, provided with the suction opening 401, of the suction device 4 and the end face of the liquid collection structure 3. The size of the bump may be as small as possible to reduce the resistance to the flow of liquid.

In some embodiments, the end face of the liquid collection structure 3 is provided with multiple drainage ribs which extend radially outward from a position corresponding to the suction opening 401. The drainage ribs are configured to guide and drain liquid on the end face. The multiple drainage ribs extending radially outward to the periphery of the liquid collection structure 3 guide the leaking liquid at the periphery of the end face of the liquid collection structure 3 to flow towards the center where the suction opening 401 is arranged to efficiently suck the leaking liquid. In the case of providing the drainage ribs, the collection area 31 with a reduced height may be omitted to simplify the structure. Alternatively, on the basis of providing the collection area 31, the drainage ribs are provided on the end face, provided with the collection area 31, of the liquid collection structure 3, and each drainage rib has an end extending to the edge of the collection area 31.

In some embodiments, referring to FIGS. 1 to 2, the liquid cooling system includes multiple liquid collection structures 3, and the suction device 4 includes negative-pressure channels respectively corresponding to the liquid collection structures 3. The multiple liquid collection structures 3 are arranged according to the possible leakage locations of the liquid cooling system, so as to better collect the leaking liquid. The suction device 4 is provided with the negative-pressure channels corresponding to the liquid collection structures 3, and the negative-pressure channels are connected to the suction apparatus to suction the leaking liquid in the liquid collection structures 3.

In some embodiments, the negative-pressure channels corresponding to the liquid collection structures 3 are in communication with each other. Thus, only a single suction apparatus is required to be provided for the negative-pressure channels to realize synchronous suction of the negative-pressure channels. The structure is simple and the cost is low. In other embodiments, a separate suction apparatus may be provided for each negative-pressure channel.

In some embodiments, the liquid cooling system further includes a detection device for detecting liquid in the liquid collection structure 3. The suction apparatus is configured to be started when it is detected a preset collection amount of liquid in the liquid collection structure 3 by the detection device detects. The suction apparatus may be not started when no leakage is detected by the detection device, and may be started when a leakage is detected by the detection device to suction the leaking liquid. The above arrangement reduces the energy consumption of the liquid cooling system and avoids unnecessary negative pressure environments. The preset collection amount may be set as needed. For example, the suction apparatus is started when the presence of liquid in the liquid collection structure 3 is detected, or the suction apparatus is started when the amount of the leaking liquid in the liquid collection structure 3 is detected to reach an upper limit of liquid collected in the liquid collection structure 3. The detection device may be a conventional detection structure such as a liquid sensor or a detection tape for detecting liquid leakage, which is not specifically limited here. In other embodiments, visual inspection may be possible, and the suction apparatus may be activated when liquid leakage is observed visually. Alternatively, the suction apparatus may be always kept started during the operation of the liquid cooling system.

Based on the liquid cooling system according to the above embodiments, a server is further provided according to the present application. The server includes any liquid cooling system described above. Since the server includes the liquid cooling system described above, and brings about the beneficial effects as described in the above embodiments.

The embodiments in the specification are described in a progressive manner, and each embodiment focuses on the difference from other embodiments. Same and similar parts in each embodiment may be referred to each other.

The above description of the embodiments is provided to enable those skilled in the art to implement or use the present application. Various modifications to the embodiments are apparent to those skilled in the art. General principles defined herein may be implemented in other embodiments without departing from spirits or scopes of the present application. Therefore, the present application is not limited to the embodiments shown herein, but is to be accorded the widest scope consistent with the principles and novel features disclosed herein.

1. A liquid cooling system comprising:
a liquid cooling body for exchanging heat with a heating element;
a liquid guide tube communicated with the liquid cooling body;
a liquid collection structure configured to collect liquid leaking from at least one of the liquid cooling body and the liquid guide tube; and
a suction device having a negative-pressure channel, wherein the negative-pressure channel has a suction opening, is arranged at the liquid collection structure, and is configured to be connected to a suction apparatus so that liquid in the liquid collection structure can be pumped into the negative-pressure channel and be discharged or stored through the negative-pressure channel.

2. The liquid cooling system according to claim 1, wherein the liquid collection structure has a collection area with a reduced height, and the suction opening is arranged at the collection area.

3. The liquid cooling system according to claim 2, wherein the suction device comprises a suction tube and a connector, and
wherein the connector is fixedly arranged on the liquid collection structure, and a portion of the connector extends above the collection area and is connected to the suction tube.

4. The liquid cooling system according to claim 3, wherein a protruding portion is provided on a bottom surface, facing the collection area, of the connector, and the protruding portion extends into the collection area,
wherein a first preset gap is formed between a bottom surface of the protruding portion and a bottom surface of the collection area, and a second preset gap is formed between an outer circumferential surface of the protruding portion and a side wall of the collection area, and
where the connector is provided with a through hole (402) at a position corresponding to the collection area, and the suction tube is disposed at the through hole (402).

5. The liquid cooling system according to claim 3, wherein
at least part of a projection of the connector on a plane, where an edge of a top of the collection area is located, falls within the collection area; and/or,
a bottom surface of a portion, which is located above the collection area, of the connector is located at a preset distance above the top of the collection area.

6. The liquid cooling system according to claim 3, wherein the suction tube is threadedly connected to the connector.

7. The liquid cooling system according to claim 1, comprising a plurality of liquid collection structures, wherein the suction device comprises negative-pressure channels respectively corresponding to the plurality of liquid collection structures, and the negative-pressure channels are in communication with each other.

8. The liquid cooling system according to claim 1, further comprising a detection device for detecting the liquid in the liquid collection structure, wherein the suction apparatus is configured to be activated if a preset amount of liquid is detected in the liquid collection structure by the detection device.

9. The liquid cooling system according to claim 1, wherein a bump is provided on an end face, which is provided with the suction opening, of the suction device, and is configured to abut against an end face of the liquid collection structure so that a gap is formed between the end face provided with the suction opening of the suction device and the end face of the liquid collection structure.

10. The liquid cooling system according to claim 2, further comprising a detection device for detecting the liquid in the liquid collection structure, wherein the suction apparatus is configured to be activated if a preset amount of liquid is detected in the liquid collection structure by the detection device.

11. The liquid cooling system according to claim 3, further comprising a detection device for detecting the liquid in the liquid collection structure, wherein the suction apparatus is configured to be activated if a preset amount of liquid is detected in the liquid collection structure by the detection device.

12. The liquid cooling system according to claim 4, further comprising a detection device for detecting the liquid in the liquid collection structure, wherein the suction apparatus is configured to be activated if a preset amount of liquid is detected in the liquid collection structure by the detection device.

13. The liquid cooling system according to claim 5, further comprising a detection device for detecting the liquid in the liquid collection structure, wherein the suction apparatus is configured to be activated if a preset amount of liquid is detected in the liquid collection structure by the detection device.

14. The liquid cooling system according to claim 6, further comprising a detection device for detecting the liquid in the liquid collection structure, wherein the suction apparatus is configured to be activated if a preset amount of liquid is detected in the liquid collection structure by the detection device.

15. The liquid cooling system according to claim 2, wherein a bump is provided on an end face, which is provided with the suction opening, of the suction device, and is configured to abut against an end face of the liquid collection structure so that a gap is formed between the end face provided with the suction opening of the suction device and the end face of the liquid collection structure.

16. The liquid cooling system according to claim 3, wherein a bump is provided on an end face, which is provided with the suction opening, of the suction device, and is configured to abut against an end face of the liquid collection structure so that a gap is formed between the end face provided with the suction opening of the suction device and the end face of the liquid collection structure.

17. The liquid cooling system according to claim 4, wherein a bump is provided on an end face, which is provided with the suction opening, of the suction device, and is configured to abut against an end face of the liquid collection structure so that a gap is formed between the end face provided with the suction opening of the suction device and the end face of the liquid collection structure.

18. The liquid cooling system according to claim 5, wherein a bump is provided on an end face, which is provided with the suction opening, of the suction device, and is configured to abut against an end face of the liquid collection structure so that a gap is formed between the end face provided with the suction opening of the suction device and the end face of the liquid collection structure.

19. The liquid cooling system according to claim 6, wherein a bump is provided on an end face, which is provided with the suction opening, of the suction device, and is configured to abut against an end face of the liquid collection structure so that a gap is formed between the end face provided with the suction opening of the suction device and the end face of the liquid collection structure.

20. A server, comprising the liquid cooling system according to claim 1.
